(19) United States
(12) Patent Application Publication
(10) Pub. No.: US 2017/0040422 A1
(43) Pub. Date: Feb. 9, 2017

(54) SEMICONDUCTOR DEVICES INCLUDING A METAL OXIDE SEMICONDUCTOR STRUCTURE

(71) Applicant: SAMSUNG ELECTRONICS CO., LTD., Suwon-si (KR)

(72) Inventors: Jae-Hyun JUNG, Suwon-si (KR); Chang-Ki JEON, Gimpo-si (KR); Min-Hwan KIM, Hwaseong-si (KR); Kyu-Ok LEE, Yongin-si (KR); Jung-Kyung KIM, Seoul (KR); Jae-June JANG, Seoul (KR); Su-Yeon CHO, Seoul (KR)

(21) Appl. No.: 15/227,490

(22) Filed: Aug. 3, 2016

(30) Foreign Application Priority Data
Aug. 6, 2015 (KR) 10-2015-0111177

(51) Int. Cl. H01L 29/40; H01L 29/66; H01L 29/788; H01L 27/115; H01L 29/78; H01L 29/10

(52) U.S. Cl. CPC H01L 29/402; H01L 29/7816; H01L 29/1095; H01L 29/408; H01L 29/1083; H01L 29/7883; H01L 27/11521; H01L 27/11526; H01L 29/66681; H01L 29/401; H01L 29/66825

(57) ABSTRACT

A semiconductor device, including a substrate; a first conductive type well and a second conductive type body region at an upper portion of the substrate; a field plate on the first conductive type well, the field plate including a semiconductor material or an insulative nitride; and a gate electrode extending in a lateral direction on the substrate from a lateral portion of the second conductive type body region to a lateral portion of the first conductive type well, the gate electrode overlapping the field plate.

### CROSS-REFERENCE TO RELATED APPLICATION

Korean Patent Application No. 10-2015-0111177, filed on Aug. 6, 2015, in the Korean Intellectual Property Office, and entitled: “Semiconductor Devices Including A Metal Oxide Semiconductor Structure,” is incorporated by reference herein in its entirety.

### BACKGROUND

1. Field

Example embodiments relate to semiconductor devices including a metal oxide semiconductor (MOS) structure.

2. Description of the Related Art

A laterally diffused metal oxide semiconductor (LDMOS) transistor may be utilized as a power transistor that may be capable of operating at a high voltage. In the LDMOS transistor, a channel region and a drain electrode may be separated by a drift region and/or a well region, and an operation of the LDMOS transistor may be controlled by a gate electrode.

A sufficient breakdown voltage may be required to realize a high-voltage operation in the LDMOS transistor.

### SUMMARY

Embodiments may be realized by providing a semiconductor device, including a substrate; a first conductive type well and a second conductive type body region at an upper portion of the substrate; a field plate on the first conductive type well, the field plate including a semiconductor material or an insulative nitride; and a gate electrode extending in a lateral direction on the substrate from a lateral portion of the second conductive type body region to a lateral portion of the first conductive type well, the gate electrode overlapping the field plate.

The field plate may include polysilicon.

The field plate may be in a top surface of the first conductive type well in a plan view.

The gate electrode may partially overlap the field plate, and may have a stepped shape.

The semiconductor device may further include a field oxide pattern between the field plate and a top surface of the first conductive type well.

The top surface of the first conductive type well may be planar, and the field oxide pattern and the field plate may have a same shape.

The semiconductor device may further include a drain region in the first conductive type well and spaced apart from the field plate in the lateral direction; a source region in the second conductive type body region; and a second conductive type contact region in the second conductive type body region, the second conductive type contact region being adjacent to the source region.

The semiconductor device may further include a gate insulation layer between the gate electrode and the field plate, the gate insulation layer covering the first conductive type well and the second conductive type body region.

The semiconductor device may further include a shallow trench isolation structure or a local oxidation silicon structure at an upper portion of the first conductive type well. The field plate may at least partially overlap the shallow trench isolation structure or the local oxidation silicon structure.

The first conductive type well may serve as a drift region.

The substrate may include a bulk substrate having a second conductive type, and an epitaxial layer grown from the bulk substrate, and the first conductive type well and the second conductive type body region may be in the epitaxial layer.

Embodiments may be realized by providing a semiconductor device, including a substrate; a first conductive type well and a second conductive type body region at an upper portion of the substrate; a source region in the second conductive type body region; a drain region in the first conductive type well; and a multi-layered structure including a first oxide layer, a first polysilicon layer, a second oxide layer and a second polysilicon layer formed sequentially from a top surface of the first conductive type well.

The semiconductor device may further include a memory cell. The substrate may include a first region and a second region, and the multi-layered structure may be at the first region, and the memory cell may be at the second region.

The memory cell may include a tunnel insulation pattern, a charge storage pattern, a dielectric pattern, and a gate line sequentially stacked from the substrate.

The tunnel insulation pattern, the charge storage pattern, the dielectric pattern, and the gate line may include same materials as those of the first oxide layer, the first polysilicon layer, the second oxide layer, and the second polysilicon layer, respectively.

The first polysilicon layer may protrude from the second polysilicon layer in a lateral direction. The second polysilicon layer may partially overlap the first conductive type well and the second conductive type body region.

Embodiments may be realized by providing a method of manufacturing a semiconductor device. In the method, a first conductive type well and a second conductive type body region may be formed at an upper portion of a substrate. A field oxide layer may be formed on the substrate to cover the first conductive type well and the second conductive type body region. A field plate layer including a semiconductor material or an insulative nitride may be formed on the field oxide layer. The field plate layer may be partially removed to form a field plate on the first conductive type well. The field oxide layer may be etched using the field plate to form a field oxide pattern. A gate insulation layer covering the field plate and the field oxide pattern may be formed on the substrate. A gate electrode may be formed on the gate insulation layer. The gate electrode may overlap lateral portions of the first conductive type well and the second conductive type body region, and may partially overlap the field plate.

The field oxide layer may be etched by a wet etching process.

The field oxide layer may be formed by thermally oxidizing a top surface of the substrate.

The field plate layer may be thinner than the gate electrode.

Embodiments may be realized by providing a semiconductor device, including a first conductive type well and a second conductive type body region at an upper portion of a substrate; a field oxide pattern on the first conductive type well; a field plate including a semiconductor material or an insulative nitride on the field oxide pattern; a gate insulation layer covering the field plate and the field oxide pattern on the substrate; and a gate electrode on the gate insulation layer, the gate electrode overlapping lateral portions of the first conductive type well and the second conductive type body region, and partially overlapping the field plate.

The semiconductor device may further include a shallow trench isolation structure at an upper portion of the first conductive type well.

A top surface of the substrate or the first conductive type well, and a top surface of the shallow trench isolation structure may be substantially coplanar with each other, and the field plate may at least partially overlap the shallow trench isolation structure.

The semiconductor device may further include a local oxidation of silicon structure at an upper portion of the first conductive type well.

The local oxidation of silicon structure may protrude from a top surface of the first conductive type well, and the field oxide pattern and the field plate may at least partially overlap the local oxidation of silicon structure.

### BRIEF DESCRIPTION OF THE DRAWINGS

Features will become apparent to those of skill in the art by describing in detail exemplary embodiments with reference to the attached drawings in which:

FIGS. 1 and 2 illustrate a top plan view and a cross-sectional view, respectively, of a semiconductor device in accordance with example embodiments;

FIGS. 3 to 13 illustrate cross-sectional views of stages in a method of manufacturing a semiconductor device in accordance with example embodiments;

FIG. 14 illustrates a cross-sectional view of a semiconductor device in accordance with some example embodiments;

FIG. 15 illustrates a cross-sectional view of a semiconductor device in accordance with some example embodiments;

FIGS. 16 and 17 illustrate cross-sectional views of semiconductor devices in accordance with some example embodiments; and

FIG. 18 illustrates a cross-sectional view of a semiconductor device in accordance with example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section.

Spatially relative terms, such as “beneath,” “below,” “lower,” “above,” “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to be limiting.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Unless otherwise defined, all terms (including technical and scientific terms) used herein have the same meaning as commonly understood by one of skill in the art. It will be further understood that terms, such as those defined in commonly used dictionaries, should be interpreted as having a meaning that is consistent with their meaning in the context of the relevant art and will not be interpreted in an idealized or overly formnal sense unless expressly so defined herein.

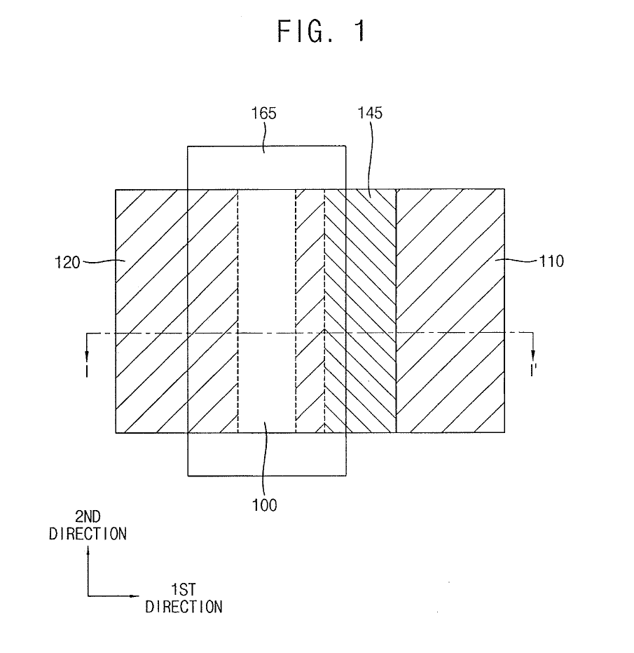

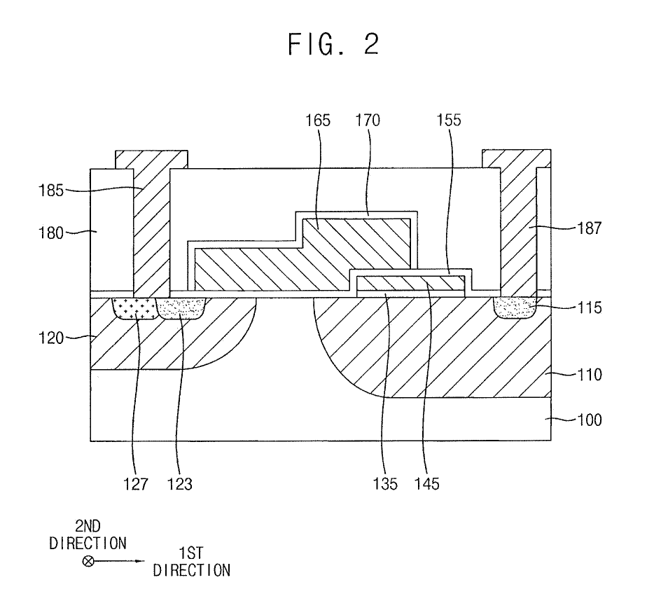

FIGS. 1 and 2 illustrate a top plan view and a cross-sectional view, respectively, of a semiconductor device in accordance with example embodiments. For example, FIG. 2 illustrates a cross-sectional view taken along a line I-I′ indicated in FIG. 1.

In example embodiments, FIGS. 1 and 2 illustrate a laterally diffused metal oxide semiconductor (LDMOS) device.

Referring to FIGS. 1 and 2, the semiconductor device may include a first conductive type well 110 and a second conductive type body region 120 formed at, e.g., both lateral portions of a substrate 100, a field plate 145 on the first conductive type well 110, and a gate electrode 165 that may partially cover the second conductive type body region 120 and the first conductive type well 110, and may partially overlap the field plate 145 with respect to a gate insulation layer 155

For convenience of descriptions, the first conductive type well 110, the second conductive type body region 120, the field plate 145 and the gate electrode 165 are only illustrated in FIG. 1, and other elements are illustrated in FIG. 2.

The substrate 100 may include a silicon (Si) substrate, a germanium (Ge) substrate or a Si—Ge substrate. In some embodiments, a silicon-on-insulator (SOI) substrate or a germanium-on-insulator (GOI) substrate may be used as the substrate 100.

In some embodiments, an epitaxial layer may be formed on the substrate 100, and the first conductive type well 110 and the second conductive type body region 120 may be formed in the eptaxial layer.

The first conductive type well 110 and the second conductive type body region 120 may be formed at an upper portion of the substrate 100.

In example embodiments, the first conductive type well 110 may include N-type impurities such as phosphorous (P) or arsenic (As), and the second conductive type body region 120 may include P-type impurities such as boron (B). The semiconductor device may be provided as an N-type LDMOS (N-LDMOS) device.

In an embodiment, if a first conductive type and a second conductive type are defined by a P-type impurity and an N-type impurity, the semiconductor device may be provided as a P-type LDMOS (P-LDMOS) device.

Hereinafter, detailed descriptions will be provided based on a construction of the N-LDMOS device.

In some embodiments, the first conductive type well 110 may serve as an N-type drift region. A portion of the substrate 100 between the first conductive type well 110 and the second conductive type body region 120 may serve as a channel region.

The first conductive type well 110 and the second conductive type body region 120 may be spaced apart from each other in a first direction (e.g., a lateral direction) parallel to a top surface of the substrate 100.

A drain region 115 may be formed at an upper portion of the substrate 100 within the first conductive type well 110. The drain region 115 may include impurities of the first conductive type, and may serve as, e.g., an N+ region.

In some example embodiments, an oxide layer may not be included in the first conductive type well 110. For example, a local oxidation of silicon (LOCOS) oxide layer or a shallow trench isolation (STI) oxide layer may not be formed in the first conductive type well 110.

A source region 123 and a second conductive type contact region 127 may be formed at an upper portion of the substrate 100 within the second conductive type body region 120. In example embodiments, the source region 123 and the second conductive type contact region 127 may serve as an N+ region and a P+ region respectively.

The source region 123 and the second conductive type contact region 127 may be in contact with each other in the first direction. The source region 123 may be more adjacent, e.g., closer, to the channel region or the first conductive type well 110 than the second conductive type contact region 127.

In example embodiments, the field plate 145 may be disposed over the first conductive type well 110. In some embodiments, a field oxide pattern 135 may be interposed between the field plate 145 and the first conductive type well 110.

As illustrated in FIG. 1, the field plate 145 may be fully included in the first conductive type well 110 in a plan view. For example, the field plate 145 may extend in the second direction (e.g., a longitudinal direction) that may be parallel to the top surface of the substrate 100 and perpendicular to the first direction.

The field oxide pattern 135 may be disposed under the field plate 145, and may have a shape substantially the same as or similar to that of the field plate 145.

In example embodiments, the field plate 145 may include a semiconductor material. For example, the field plate 145 may include doped or undoped polysilicon. In some embodiments, the field plate 145 may include an insulative nitride, e.g., silicon nitride. The field oxide pattern 135 may include silicon oxide.

The gate insulation layer 155 may be formed on the substrate 100, and may cover the field plate 145 and the field oxide pattern 135. In some embodiments, the gate insulation layer 155 may extend in the first direction, and may also cover the second conductive type body region 120, the substrate 100 and the first conductive type well 110.

The gate insulation layer 155 may include an oxide, e.g., silicon oxide. In some embodiments, the gate insulation layer 155 may be substantially merged with the field oxide pattern 135.

The gate electrode 165, as illustrated in FIG. 1, may cover portions of the second conductive type body region 120, the substrate 100 (e.g., the channel region) and the first conductive type well 110 along the first direction. In example embodiments, the gate electrode 165 may partially overlap the field plate 145 over the first conductive type well 110, and the gate electrode 165 may include a stepped portion due to the field plate 145. The gate electrode 165 may extend in the second direction.

The gate electrode 165 may include polysilicon. In some embodiments, the gate electrode 165 may include a conductive material, e.g., a metal, a metal nitride and/or a metal suicide.

The first conductive type well 110 and the second conductive type body region 120 may be adjacent to both lateral portions of the gate electrode 165. The source region 123 may overlap a lateral portion of the gate electrode 165. The second conductive type contact region 127 may be in contact with the source region 123, and may be spaced apart from the lateral portion of the gate electrode 165 in the first direction.

In some embodiments, a gate oxide layer 170 may be formed on a surface of the gate electrode 165. The gate oxide layer 170 may include, e.g., silicon oxide or a metal oxide. The gate oxide layer 170 may substantially serve as a spacer.

An insulating interlayer 180 may be formed on the substrate 100, and may cover the gate insulation layer 155, the field plate 145 and the gate electrode 165. The insulating interlayer 180 may include a silicon oxide-based material, e.g., plasma enhanced oxide (PEOX), tetraethyl orthosilicate (TEOS), flowable oxide (FOX), or silicate glass.

In some embodiments, the insulating interlayer 180 may be substantially merged with the gate oxide layer 170 and/or the gate insulation layer 155.

A source electrode 185 and a drain electrode 187 may extend through the insulating interlayer 180 and the gate insulation layer 155 to be electrically connected to or in contact with the source region 123 and the drain region 115, respectively.

The source electrode 185 may be also electrically connected to or in contact with the second conductive type contact region 127 together with the source region 123.

The source electrode 185 and the drain electrode 187 may include a conductive material, e.g., a metal such as tungsten, copper or aluminum, a metal nitride, a metal suicide and/or doped polysilicon.

In some embodiments, a metal silicide pattern may be further formed between the source electrode 185 and the source region 123/the second conductive type contact region 127, and/or between the drain electrode 187 and the drain region 115.

According to example embodiments as described above, the field plate 145 may be disposed on the first conductive type well 110 having a substantially planar top surface. For example, the field plate 145 may be partially inserted into the gate electrode 165 between the drain electrode 187 and the gate electrode 165. The field plate 145 may be thinner than the gate electrode 165.

The field plate 145 may be insulated from the substrate 100 or the first conductive type well 110 by the field oxide pattern 135. The field plate 145 may be insulated from the gate electrode 165 by the gate insulation layer 155, and the field oxide pattern 135, the field plate 145, the gate insulation layer 155 and the gate electrode 165 may be sequentially stacked from the first conductive type well 110.

In some embodiments, an oxide-polysilicon-oxide-polysilicon stacked structure may be formed on the first conductive type well 110, and a double-layered polysilicon structure may be disposed on the first conductive type well 110.

In some embodiments, an oxide-nitride-oxide-polysilicon stacked structure may be formed on the first conductive type well 110. In some embodiments, an oxide-polysilicon-oxide-metal stacked structure or an oxide-nitride-oxide-metal stacked structure may be formed on the first conductive type well 110.

As described above, the stacked structure including the field plate 145 may be provided on the first conductive type well 110 serving as, e.g., the N-type drift region to alleviate an electric field concentration generated between the gate electrode 165 and the drain electrode 187 of the LDMOS device. Endurance to a high voltage of the semiconductor device may be improved, and a desired breakdown voltage may be obtained.

In example embodiments, an oxide structure including, e.g., an STI oxide layer or a LOCOS oxide layer may be excluded in the first conductive type well 110 of the semiconductor device, and the field oxide pattern 135 and the field plate 145 may be formed on the substantially planar top surface of the first conductive type well 110. An increase of a resistance (e.g., an on-resistance (Ron)) caused from a bypass current by the STI oxide layer or the LOCOS oxide layer may be avoided.

The resistance may be reduced while achieving the desired breakdown voltage so that the LDMOS device having an improved operational speed may be realized.

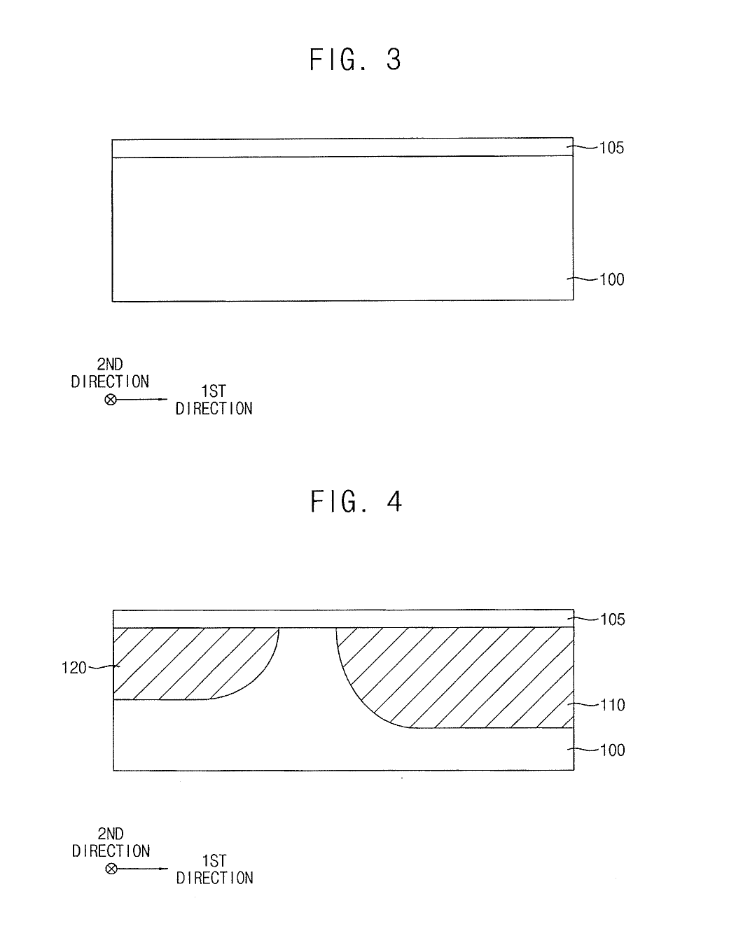

FIGS. 3 to 13 illustrate cross-sectional views of stages in a method of manufacturing a semiconductor device in accordance with example embodiments. For example, FIGS. 3 to 13 illustrate stages in a method of manufacturing the semiconductor device of FIGS. 1 and 2.

Referring to FIG. 3, a pad oxide layer 105 may be formed on a substrate 100.

The substrate 100 may be prepared from a Si substrate, a Ge substrate, a Si—Ge substrate, an SOI substrate or a GOI substrate. In some embodiments, an epitaxial layer grown from, e.g., the Si substrate or the Ge substrate may be used as the substrate 100.

The pad oxide layer 105 may be formed by a thermal oxidation process on a top surface of the substrate 100.

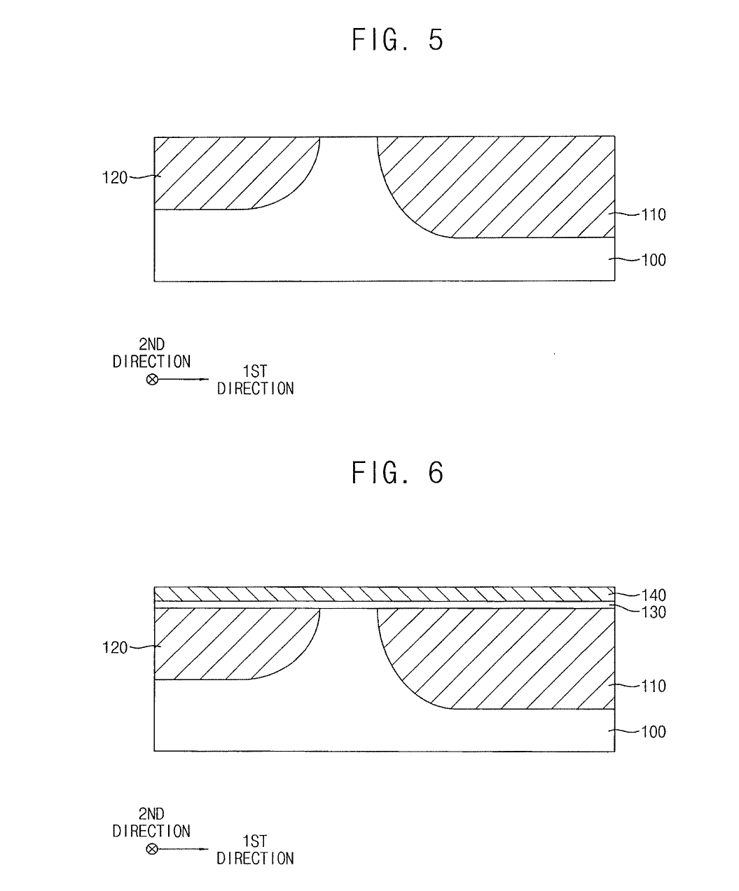

Referring to FIG. 4, a first conductive type impurity and a second conductive type impurity may be implanted at an upper portion of the substrate 100 by an ion-implantation process to form a first conductive type well 110 and a second conductive type body region 120. In example embodiments, the first conductive type impurity may include an N-type impurity such as P or As, and the second conductive type impurity may include a P-type impurity such as B. The first conductive type well 110 and the second conductive type body region 120 may serve as an N-drift region and a P-type body region, respectively, of an N-LDMOS device.

In an embodiment, the first conductive type impurity and the second conductive type impurity may include the P-type impurity and the N-type impurity, respectively, and a P-LDMOS device may be manufactured.

In example embodiments, a first ion-implantation mask partially exposing an upper portion of the substrate 100 may be formed using a photoresist. The first conductive type impurity may be injected through the first ion-implantation mask to form the first conductive type well 110.

The first ion-implantation mask may be removed by an ashing process and/or a strip process, and a second ion-implantation mask covering the first conductive well 110 may be formed. The second conductive type impurity may be injected through the second ion-implantation mask to form the second conductive type body region 120 that may be spaced apart from the first conductive type well 110 in a first direction (e.g., a lateral direction). The second ion-implantation mask may be removed by an ashing process and/or a strip process.

During the ion-implantation process as described above, a surface damage of the substrate 100 may be prevented by the pad oxide layer 105.

Referring to FIG. 5, the pad oxide layer 105 that may be damaged by the ion-implantation process may be removed. For example, the pad oxide layer 105 may be removed using an etchant solution including a fluoric acid component.

Referring to FIG. 6, a field oxide layer 130 covering the first conductive type well 110 and the second conductive type body region 120 may be formed on the substrate 100. A field plate layer 140 may be formed on the field oxide layer 130.

For example, the field oxide layer 130 may be formed by a thermal oxidation process on the top surface of the substrate 100. In some embodiments, the field oxide layer 130 may be formed by a deposition process, e.g., a chemical vapor deposition (CVD) process.

In example embodiments, the field plate layer 140 may be formed of a material that may have an etching selectivity greater than that of an oxide. In some embodiments, the field plate layer 140 may be formed of a semiconductor material such as polysilicon optionally doped with impurities. In some embodiments, the field plate layer 140 may be formed of an insulative nitride-based material such as silicon nitride.

For example, the field plate layer 140 may be formed by, for example, a sputtering process, an atomic layer deposition (ALD) process, a plasma enhanced CVD (PECVD) process, or a CVD process.

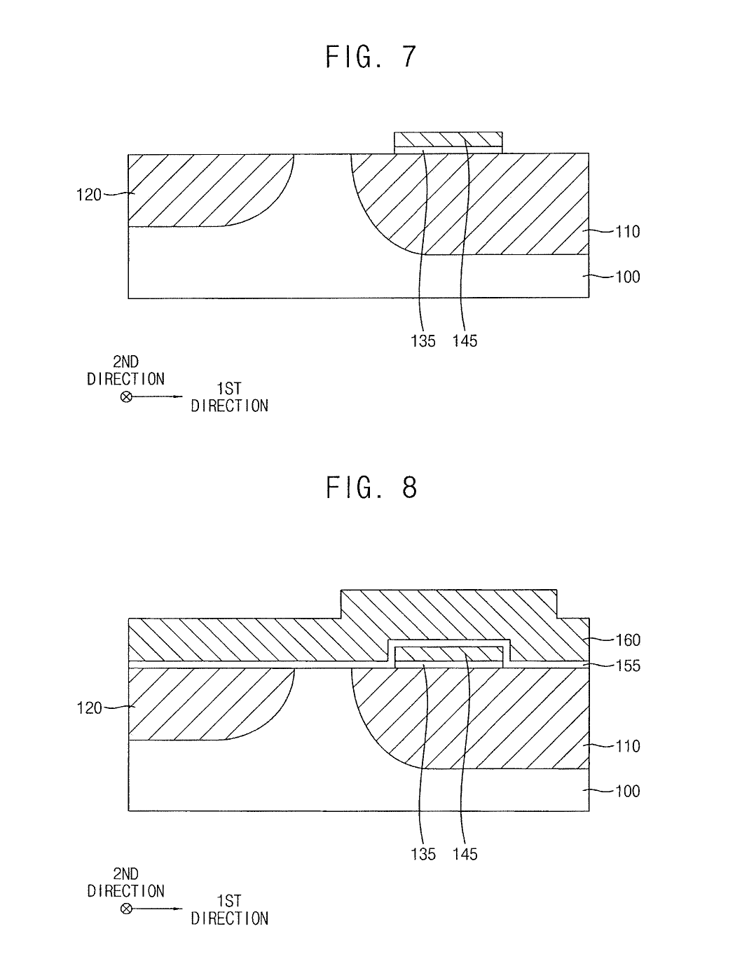

Referring to FIG. 7, the field plate layer 140 and the field oxide layer 130 may be sequentially etched to form a field plate 145 and a field oxide pattern 135. As illustrated in FIG. 1, the field plate 145 and the field oxide pattern 135 may be included in the first conductive type well 110 in a plan view, and may extend in a second direction (e.g., a longitudinal direction)

If the field plate layer 140 includes polysilicon, the field plate 145 may be formed by, e.g., a gas phase etching (GPE) process using a chlorine (Cl₂) gas. If the field plate layer 140 includes the nitride-based material, the field plate 145 may be formed by a wet etching process using, e.g., phosphoric acid and/or a nitric acid.

The field oxide pattern 135 may be formed by an isotropic etching (e.g., a dry etching) process or an anisotropic etching (e.g., a wet etching) process in which the field plate 145 may be used as an etching mask. In some embodiments, the field oxide layer 130 may be patterned by the wet etching process using, e.g., a fluoric acid-based etchant solution for implementing a fine design rule.

Referring to FIG. 8, a gate insulation layer 155 covering the field oxide pattern 135 and the field plate 145 may be formed on the substrate 100, the first conductive type well 110 and the second conductive type body region 120, and a gate electrode layer 160 may be formed on the gate insulation layer 155.

The gate insulation layer 155 may be formed conformally along surfaces of the substrate 100 and the field plate 145. For example, the gate insulation layer 155 may be formed of silicon oxide by a CVD process.

The gate electrode layer 160 may be thicker than the field plate layer 140, and may protrude at an area overlapping the field plate 145. In example embodiments, the gate electrode layer 160 may be formed of polysilicon substantially the same as or similar to that of the field plate layer 140.

In some embodiments, the gate electrode layer 160 may be formed of a metal, a metal silicide and/or a metal nitride. For example, the gate electrode layer 160 may be formed by a sputtering process or an ALD process.

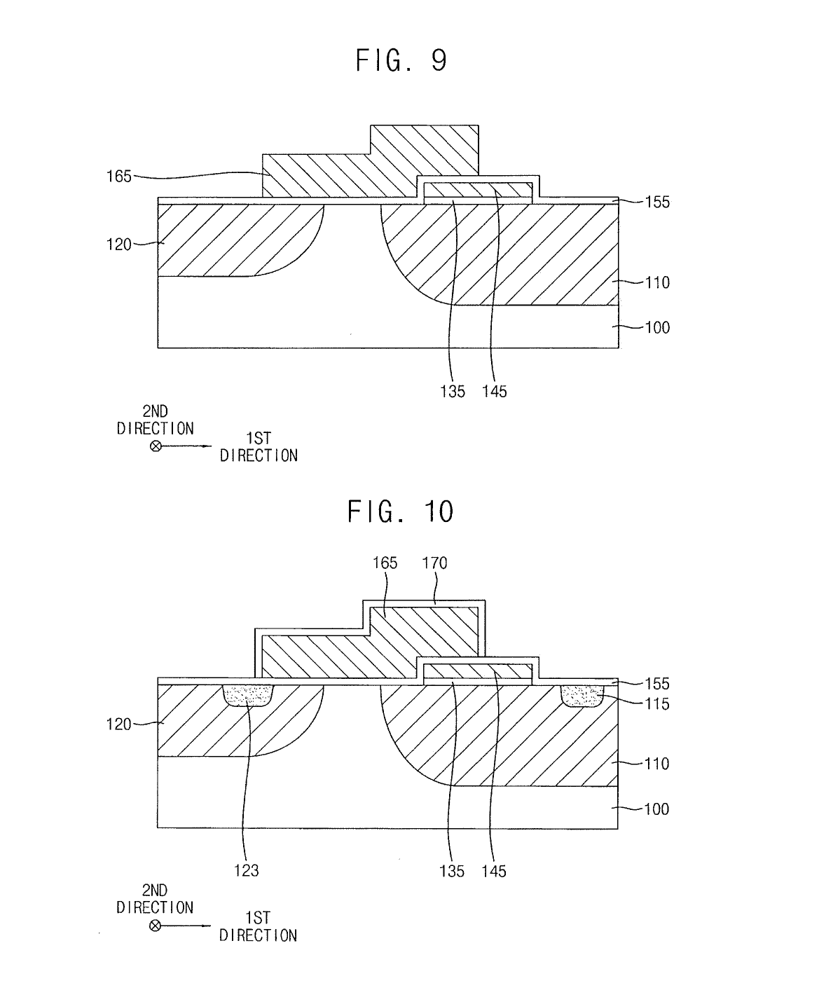

Referring to FIG. 9, the gate electrode layer 160 may be partially etched to form a gate electrode 165.

The gate electrode 165 may overlap a lateral portion of the first conductive type well 110 and a lateral portion of the second conductive type body region 120, and may partially overlap the field plate 145 with respect to the gate insulation layer 155. As illustrated in FIG. 1, the gate electrode 165 may extend in the second direction.

The gate electrode 165 may include a protrusion at the area overlapping the field plate 145. For example, the gate electrode 165 may have a stepped shape.

In some embodiments, if the gate electrode layer 160 is formed of polysilicon, the gate electrode 165 may be formed by a GPE process using, e.g., a chlorine gas. In some embodiments, if the gate electrode layer 160 includes the metal, the gate electrode 165 may be formed by a wet etching process using, e.g., a peroxide-based etchant solution.

Referring to FIG. 10, a gate oxide layer 170 may be formed on a surface of the gate electrode 165.

The gate oxide layer 170 may be formed by thermally oxidizing the surface of the gate electrode 165. If the gate electrode 165 includes polysilicon, the gate oxide layer 170 may be formed of silicon oxide. If the gate electrode 165 includes the metal, the gate oxide layer 170 may be formed of a metal oxide.

In some embodiments, the gate oxide layer 170 may be formed by a deposition process, e.g., a CVD process or an ALD process, and the gate oxide layer 170 may be substantially merged with the gate insulation layer 155.

The gate electrode 165 may be protected by the gate oxide layer 170 during a subsequent ion-implantation process. In some embodiments, the formation of the gate oxide layer 170 may be omitted.

The first type impurity may be implanted by the ion-implantation process to form a source region 123 and a drain region 115 at an upper portion of the substrate 100.

In some embodiments, the drain region 115 may be formed in the first conductive type well 110, and may be spaced apart from the field plate 145 in the first direction. The source region 123 may be formed in the second conductive type body region 120, and may partially overlap the gate electrode 165.

The source region 123 and the drain region 115 may serve as N+ regions. In an embodiment, if the semiconductor device is fabricated as a P-LDMOS device, the source region 123 and the drain region 115 may serve as P+ regions.

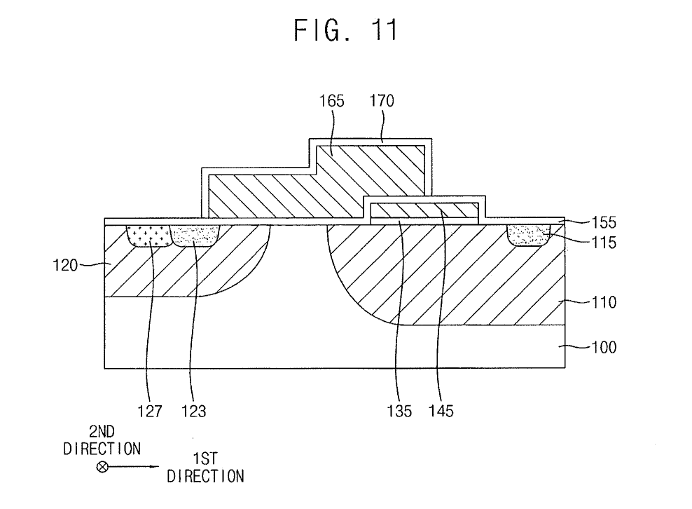

Referring to FIG. 11, the second conductive type impurity region may be implanted by an additional ion-implantation process to form a second conductive type contact region 127 in the second conductive type body region 120. The second conductive type contact region 127 may be in contact with the source region 123 in the first direction.

The second conductive type contact region 127 may serve as a P+ region. In an embodiment, if the semiconductor device is fabricated as the P-LDMOS device, the second conductive type contact region 127 may serve as an N+ region.

In some embodiments, the second conductive type contact region 127 may surround the source region 123.

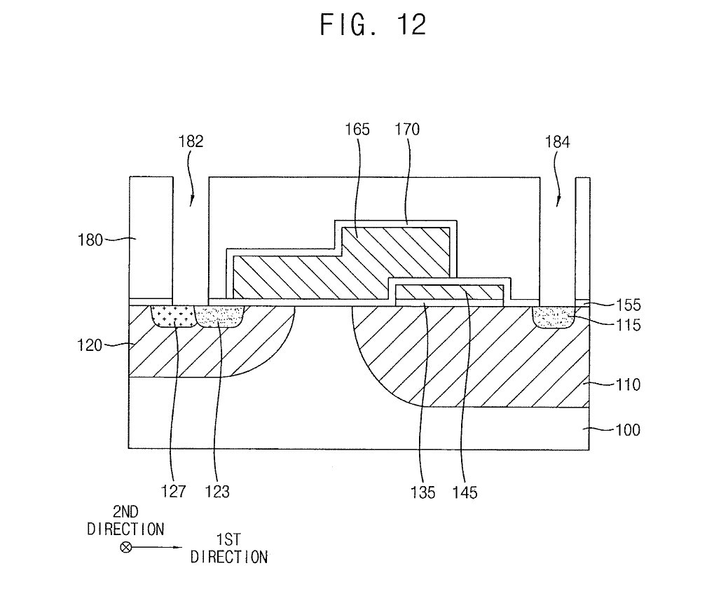

Referring to FIG. 12, an insulating interlayer 180 covering the gate oxide layer 170 and/or the gate electrode 165 may be formed on the gate insulation layer 155. The insulating interlayer 180 may be formed of silicon oxide, e.g., PEOX, TEOS, FOX, silicate glass, or the like by, e.g., a CVD process.

The insulating interlayer 180 may be partially removed to form a first contact hole 182 and a second contact hole 184. The second conductive type contact region 127 and the source region 123 may be exposed together through the first contact hole 182. The drain region 115 may be exposed through the second contact hole 184.

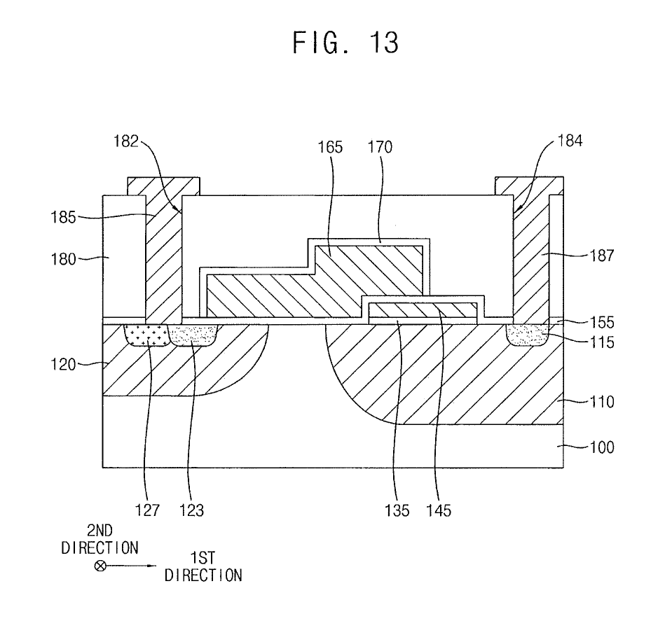

Referring to FIG. 13, a source electrode 185 and a drain electrode 187 may be formed in the first contact hole 182 and the second contact hole 184, respectively.

For example, a conductive layer filling the first and second contact holes 182 and 184 may be formed on the insulating interlayer 180. The conductive layer may be partially etched to form the source electrode 185 and the drain electrode 187. The conductive layer may be formed of a metal, a metal silicide, a metal nitride and/or doped polysilicon by, e.g., a sputtering process or an ALD process.

The source electrode 185 may directly contact the second conductive type contact region 127 and the source region 123, and the drain electrode 187 may directly contact the drain region 115.

In some embodiments, a metal layer may be formed on bottoms of the first contact hole 182 and the second contact hole 184, the metal layer may be reacted with the source region 123/the second conductive type contact region 127, and the drain region 115 by a thermal treatment to form a suicide pattern. The source electrode 185 and the drain electrode 187 may be in contact with the suicide pattern.

According to example embodiments as described above, the field plate 145 for alleviating an electric field concentration may be formed of polysilicon or a nitride which may be finely patterned with a high etching selectivity compared to an oxide. An oxide pattern including, e.g., a LOCOS pattern or an STI pattern may be omitted, and the field plate 145 having a fine width may be formed at a desired region.

An on-resistance may be decreased without damaging the substrate 100, and the semiconductor device having an improved design rule may be achieved.

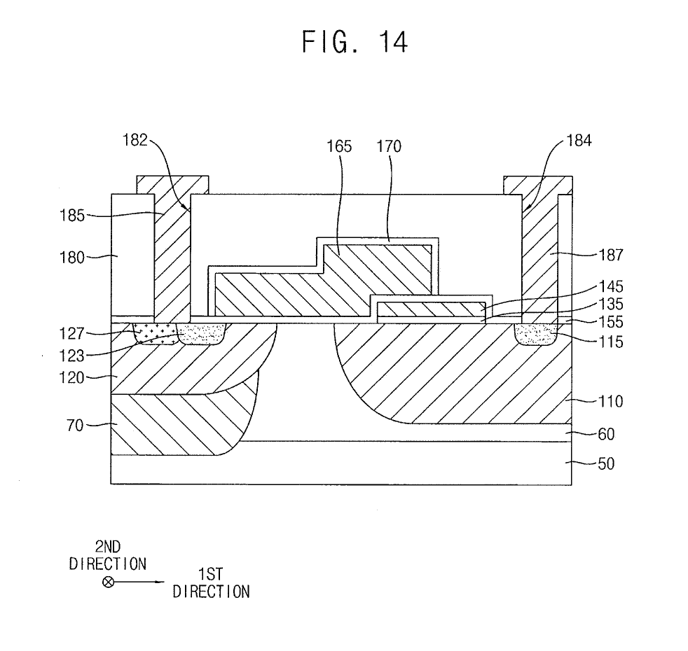

FIG. 14 illustrates a cross-sectional view of a semiconductor device in accordance with some example embodiments. Detailed descriptions on elements and/or structures substantially the same as or similar to those illustrated with reference to FIGS. 1 and 2 are omitted herein. Like reference numerals are used to designate like elements.

Referring to FIG. 14, the first conductive type well 110 and the second conductive type body region 120 may be formed in an epitaxial layer 60 grown from a bulk substrate 50 by, e.g., a selective epitaxial growth (SEG) process.

In some embodiments, the bulk substrate 50 and the epitaxial layer 60 may be a second conductive type. For example, in an N-LDMOS device, the bulk substrate 50 and the epitaxial layer 60 may be a P+ type and a P− type, respectively.

A second conductive type deep well 70 may be formed between the bulk substrate 50 and the second conductive type body region 120. For example, in the N-LDMOS device, the second conductive deep well 70 may serve as a P+ type deep well or a P+ type sinker.

The second conductive type deep well 70 may be in contact with the second conductive type body region 120, and a vertical electric field may be generated by a source voltage. A generation of a lateral electric field may be facilitated between the second conductive type body region 120 and the first conductive type well 110.

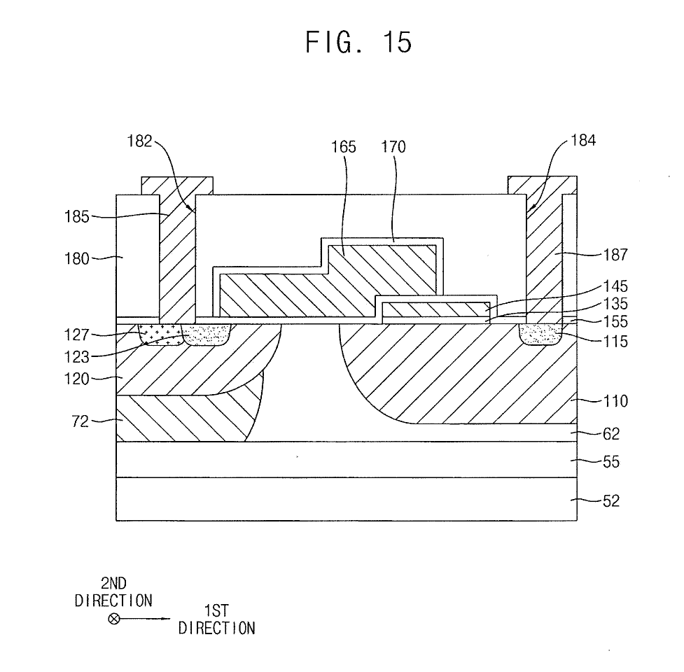

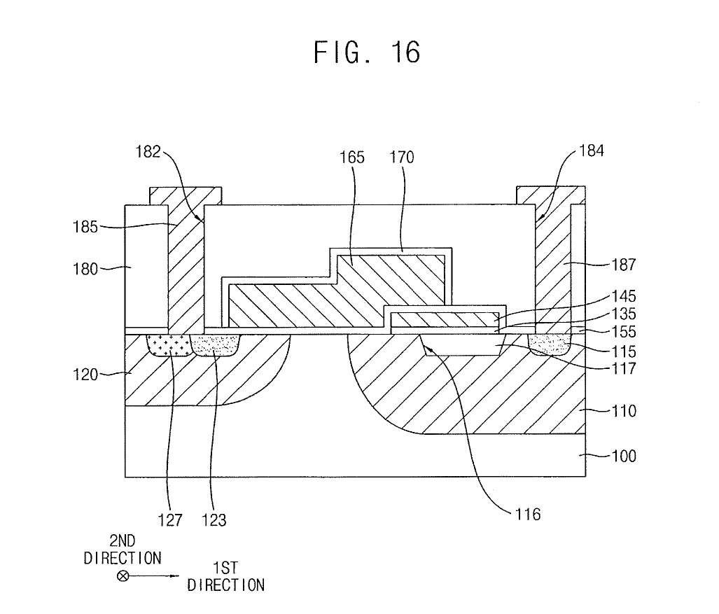

FIG. 15 illustrates a cross-sectional view of a semiconductor device in accordance with some example embodiments. Detailed descriptions on elements and/or structures substantially the same as or similar to those illustrated with reference to FIGS. 1 and 2, or FIG. 14 are omitted herein. Like reference numerals are used to designate like elements.

Referring to FIG. 15, the semiconductor device may further include a buried layer 55 formed between a bulk substrate 52 and an epitaxial layer 62.

In some embodiments, the buried layer 55 may be formed by implanting a first conductive type impurity at an upper portion of the bulk substrate 52. For example, in an N-LDMOS device, the buried layer 55 may serve as an N+ type layer. In some embodiments, the buried layer 55 may serve as a P+ type layer.

The epitaxial layer 62 may be formed from the buried layer 55 by, e.g., an SEG process. A second conductive type deep well 72 may be formed between the buried layer 55 and the second conductive type body region 120. The second conductive type deep well 72 may be in contact with the buried layer 55 and the second conductive type body region 120.

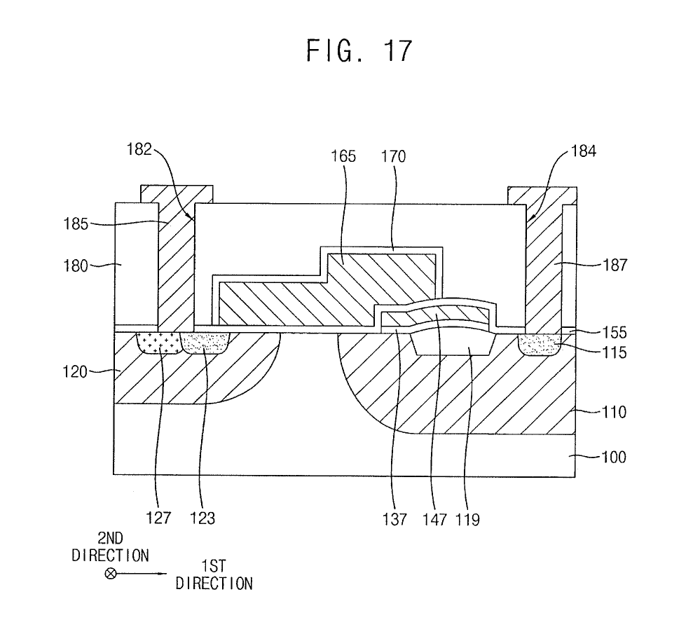

FIGS. 16 and 17 illustrate cross-sectional views of semiconductor devices in accordance with example embodiments. Detailed descriptions on elements and/or structures substantially the same as or similar to those illustrated with reference to FIGS. 1 and 2 are omitted herein. Like reference numerals are used to designate like elements.

Referring to FIGS. 16 and 17, an insulation layer may be formed in the first conductive type well 110 (e.g., a drift region) of, e.g., the LDMOS device.

As illustrated in FIG. 16, an STI structure 117 may be formed at an upper portion of the first conductive type well 110. In example embodiments, a trench 116 may be formed at the upper portion of the first conductive type well 110. The insulation layer including silicon oxide and filling the trench 116 may be formed on the substrate 100. An upper portion of the insulation layer may be planarized by a chemical mechanical polish (CMP) process to form the STI structure 117.

A top surface of the substrate 100 or the first conductive type well 110, and a top surface of the STI structure 117 may be substantially coplanar with each other. The field plate 145 may have a substantially planar shape, and may at least partially overlap the STI structure 117.

In some embodiments, the field plate 145 may be included in the top surface of the STI structure 117 in a plan view, and the field oxide pattern 135 may be omitted.

As illustrated in FIG. 17, a LOCOS structure 119 may be formed at an upper portion of the first conductive type well 110.

The LOCOS structure 119 may be formed by locally oxidizing the upper portion of the first conductive type well 110. The LOCOS structure 119 may be inserted in the first conductive type well 110 and may protrude from a top surface of the first conductive type well 110.

In some embodiments, a field oxide pattern 137 and a field plate 147 may at least partially overlap the LOCOS structure 119, and may have stepped portions at an area overlapping the LOCOS structure 119.

In some embodiments, the field plate 147 may be included in a top surface of the LOCOS structure 119 in a plan view, and the field oxide pattern 137 may be omitted.

As described above, for example, an oxide layer may be included in the first conductive type well 110, and the field plate 135 and 137 may be further formed on the oxide layer. An electric field concentration generated at an area adjacent to a drain region may be effectively alleviated, and a breakdown voltage property may be further improved.

A thickness of the STI structure 117 or the LOCOS structure 119 may be reduced because the alleviation of the electric field concentration may be facilitated by the field plate 135 and 137, and an increase of an on-resistance due to a bypass current may be efficiently suppressed while improving a design rule.

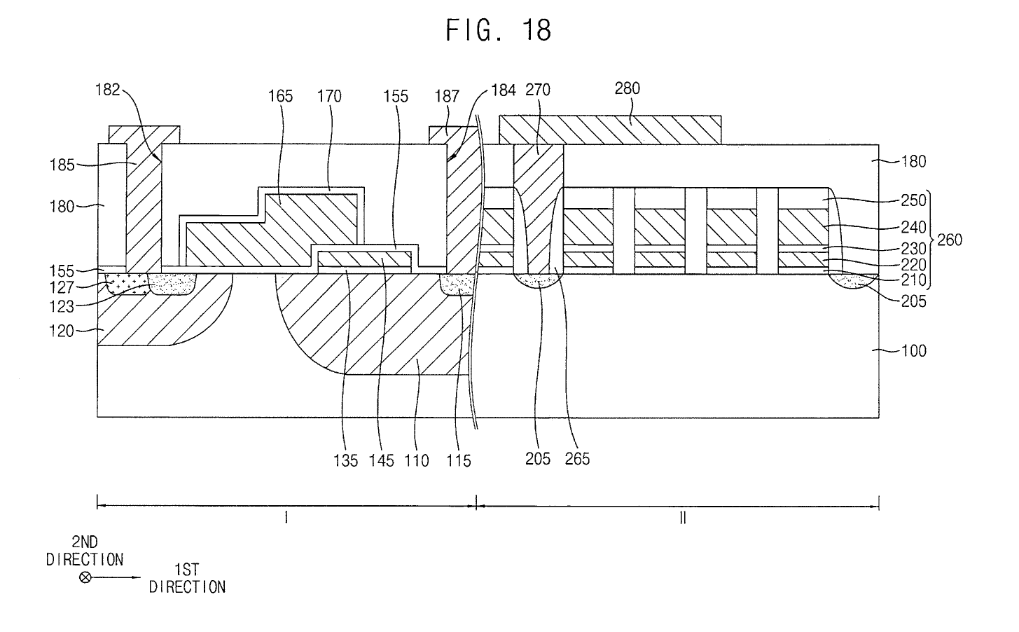

FIG. 18 illustrates a cross-sectional view of a semiconductor device in accordance with example embodiments. Detailed descriptions on elements and/or structures substantially the same as or similar to those illustrated with reference to FIGS. 1 and 2 are omitted herein. Like reference numerals are used to designate like elements.

Referring to FIG. 18, the semiconductor device may include a combination of an LDMOS device according to example embodiments and a memory device.

The LDMOS device may have elements and/or constructions substantially the same as or similar to those illustrated with reference to FIGS. 1 and 2. The memory device may include, e.g., a non-volatile flash memory device.

As illustrated in FIG. 18, a substrate 100 may be divided into a first region I and a second region II.

The LDMOS device according to example embodiments as described above may be provided at the first region I of the substrate 100. As described above, the first conductive type well 110 and the second conductive type body region 120 spaced apart from the first direction may be formed at an upper portion of the substrate 100 at the first region I. The field oxide pattern 135 and the field plate 145 including polysilicon may be disposed on the first conductive type well 110.

The gate electrode 165 may extend in the first direction on the gate insulation layer 155 from a lateral portion of the second conductive type body region 120 to a lateral portion of the first conductive type well 110, and may partially overlap the field plate 145.

In example embodiments, the LDMOS device may be utilized as, e.g., a power control transistor, an inverter and/or a booster.

The second region II of the substrate 100 may serve as a memory region.

A plurality of memory cells 260 may be arranged along the first direction on the substrate 100 at the second region II. Each memory cell 260 may extend in the second direction.

The memory cell 260 may include a tunnel insulation pattern 210, a charge storage pattern 220, a dielectric pattern 230 and a gate line 240 sequentially stacked from a top surface of the substrate 100. The gate line 240 may serve as, e.g., a coupling gate or a control gate. A gate mask 250 may be further formed on the gate line 240.

In example embodiments, the memory cell 260 may be formed from materials, deposition processes and/or etching processes for forming the field oxide pattern 135, the field plate 145, the gate insulation layer 155 and the gate electrode 165 at the first region I.

For example, the tunnel insulation pattern 210 and the charge storage pattern 220 may be formed together with the field oxide pattern 135 and the field plate 145 at the first region I, and the tunnel insulation pattern 210 and the charge storage pattern 220 may include silicon oxide and polysilicon, respectively.

The dielectric pattern 230 and the gate line 240 may be formed together with the gate insulation layer 155 and the gate electrode 165 at the first region I, and the dielectric pattern 230 and the gate line 240 may include silicon oxide and polysilicon, respectively.

In some embodiments, the gate insulation layer 155 and the dielectric pattern 230 may include a plurality of insulation layers. The gate electrode 165 and the gate line 240 may include a metal, a metal suicide and/or a metal nitride.

The gate mask 250 may include, e.g., silicon nitride or silicon oxynitride. A spacer 265 including silicon nitride or silicon oxynitride may be formed on a sidewall of the memory cell 260.

The insulating interlayer 180 may cover the gate electrode 165 and the memory cells 260 on the first region I and the second region II.

Impurity regions 205 may be formed at an upper portion of the substrate 100 between some of the memory cells neighboring each other. At least one of the impurity regions 205 may serve as a common source line (CSL).

A plug 270 may extend through the insulating interlayer 180 to be electrically connected to the impurity region 205. The plug 270 may serve as a CSL contact or a bit line contact. A conductive line 280 may be disposed on the insulating interlayer 180 to be electrically connected to the plug 270. The conductive line 280 may serve as, e.g., a bit line.

As described above, processes and/or materials for forming a non-memory device and the memory device at the first region I and the second region II may be integrated, and thus process efficiency may be improved.

According to example embodiments, a field plate including polysilicon or an insulative nitride may be formed on a drift region of, e.g., an LDMOS device. An electric field concentration between a gate electrode and a drain region may be alleviated by the field plate while achieving a desired breakdown voltage. An oxide layer in the drift region may be removed or reduced so that a bypass current may be prevented to reduce a resistance. The field plate may be formed by an improved etching selectivity, and a fine design rule may be realized in the LDMOS device.

Example embodiments may provide a semiconductor device having improved electrical and operational properties. Example embodiments may provide a method of manufacturing a semiconductor device having improved electrical and operational properties. Example embodiments relate to semiconductor devices including a gate structure and a plurality of impurity regions.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate;
a first conductive type well and a second conductive type body region at an upper portion of the substrate;
a field plate on the first conductive type well, the field plate including a semiconductor material or an insulative nitride; and
a gate electrode extending in a lateral direction on the substrate from a lateral portion of the second conductive type body region to a lateral portion of the first conductive type well, the gate electrode overlapping the field plate.

2. The semiconductor device as claimed in claim 1, wherein the field plate includes polysilicon.

3. The semiconductor device as claimed in claim 1, wherein the field plate is in a top surface of the first conductive type well in a plan view.

4. The semiconductor device as claimed in claim 3, wherein the gate electrode partially overlaps the field plate, and has a stepped shape.

5. The semiconductor device as claimed in claim 1, further comprising a field oxide pattern between the field plate and a top surface of the first conductive type well.

6. The semiconductor device as claimed in claim 5, wherein the top surface of the first conductive type well is planar, and the field oxide pattern and the field plate have a same shape.

7. The semiconductor device as claimed in claim 1, further comprising:
a drain region in the first conductive type well and spaced apart from the field plate in the lateral direction;
a source region in the second conductive type body region; and
a second conductive type contact region in the second conductive type body region, the second conductive type contact region being adjacent to the source region.

8. The semiconductor device as claimed in claim 1, further comprising a gate insulation layer between the gate electrode and the field plate, the gate insulation layer covering the first conductive type well and the second conductive type body region.

9. The semiconductor device as claimed in claim 1, further comprising a shallow trench isolation structure or a local oxidation silicon structure at an upper portion of the first conductive type well,
wherein the field plate at least partially overlaps the shallow trench isolation structure or the local oxidation silicon structure.

10. The semiconductor device as claimed in claim 1, wherein the first conductive type well serves as a drift region.

11. The semiconductor device as claimed in claim 1, wherein:
the substrate includes a bulk substrate having a second conductive type, and an epitaxial layer grown from the bulk substrate, and
the first conductive type well and the second conductive type body region are in the epitaxial layer.

12. A semiconductor device, comprising:
a substrate;
a first conductive type well and a second conductive type body region at an upper portion of the substrate;
a source region in the second conductive type body region;
a drain region in the first conductive type well; and
a multi-layered structure including a first oxide layer, a first polysilicon layer, a second oxide layer and a second polysilicon layer formed sequentially from a top surface of the first conductive type well.

13. The semiconductor device as claimed in claim 12, further comprising a memory cell,
wherein the substrate includes a first region and a second region, and
wherein the multi-layered structure is at the first region, and the memory cell is at the second region.

14. The semiconductor device as claimed in claim 13, wherein the memory cell includes a tunnel insulation pattern, a charge storage pattern, a dielectric pattern, and a gate line sequentially stacked from the substrate.

15. The semiconductor device as claimed in claim 14, wherein the tunnel insulation pattern, the charge storage pattern, the dielectric pattern, and the gate line include same materials as those of the first oxide layer, the first polysilicon layer, the second oxide layer, and the second polysilicon layer, respectively.

16. A semiconductor device, comprising:
a first conductive type well and a second conductive type body region at an upper portion of a substrate;
a field oxide pattern on the first conductive type well;
a field plate including a semiconductor material or an insulative nitride on the field oxide pattern;
a gate insulation layer covering the field plate and the field oxide pattern on the substrate; and
a gate electrode on the gate insulation layer, the gate electrode overlapping lateral portions of the first conductive type well and the second conductive type body region, and partially overlapping the field plate.

17. The semiconductor device as claimed in claim 16, further comprising a shallow trench isolation structure at an upper portion of the first conductive type well.

18. The semiconductor device as claimed in claim 17, wherein:
a top surface of the substrate or the first conductive type well, and a top surface of the shallow trench isolation structure are substantially coplanar with each other, and
the field plate at least partially overlaps the shallow trench isolation structure.

19. The semiconductor device as claimed in claim 16, further comprising a local oxidation of silicon structure at an upper portion of the first conductive type well.

20. The semiconductor device as claimed in claim 19, wherein:
the local oxidation of silicon structure protrudes from a top surface of the first conductive type well, and
the field oxide pattern and the field plate at least partially overlap the local oxidation of silicon structure.
